(19) United States
(12) Patent Application Publication
(10) Pub. No.: US 2013/0050951 A1
(43) Pub. Date: Feb. 28, 2013

(54) AIR DUCT

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/280,352

(22) Filed: Oct. 25, 2011

(30) Foreign Application Priority Data
Aug. 30, 2011 (CN) 201110252678.5

(51) Int. Cl. H05K 7/20; F24F 13/12

(52) U.S. Cl. 361/720; 454/324

(57) ABSTRACT

An air duct for guiding airflow of a fan includes a cover and an auxiliary plate. The cover includes a base plate, and a first side plate and a second side plate extending from a first side surface of the base plate. The auxiliary plate is slidably attached to the first side surface of the base plate between the first side plate and the second side plate, in a direction substantially parallel to the first and second side plates.

### BACKGROUND

1. Technical Field

The present disclosure relates to air ducts, and particularly, to an air duct used in a computer.

2. Description of Related Art

Electronic devices, such as computers, use heat dissipation assemblies for dissipating heat generated by components in the electronic devices, thus preventing the components from becoming overheated. An air duct is often used in a computer with a fan and a heat sink to dissipate heat. The air duct covers the heat sink to generate airflow to dissipate heat. However, the height of a traditional air duct is stationary, which cannot be used for heat sinks of different heights.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an air duct and a circuit board, in accordance with an embodiment.

FIG. 2 is an inverted view of the air duct of FIG. 1, wherein the air duct includes a cover and an auxiliary plate.

FIG. 3 is an exploded, isometric view of the air duct of FIG. 2.

FIG. 4 is an enlarged, inverted view of the auxiliary plate of FIG. 3.

FIG. 5 is an assembled, isometric view of FIG. 1.

FIGS. 6 and 7 are cross-sectional views taken along line VI-VI of FIG. 5, but respectively shows different usage states of the air duct.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

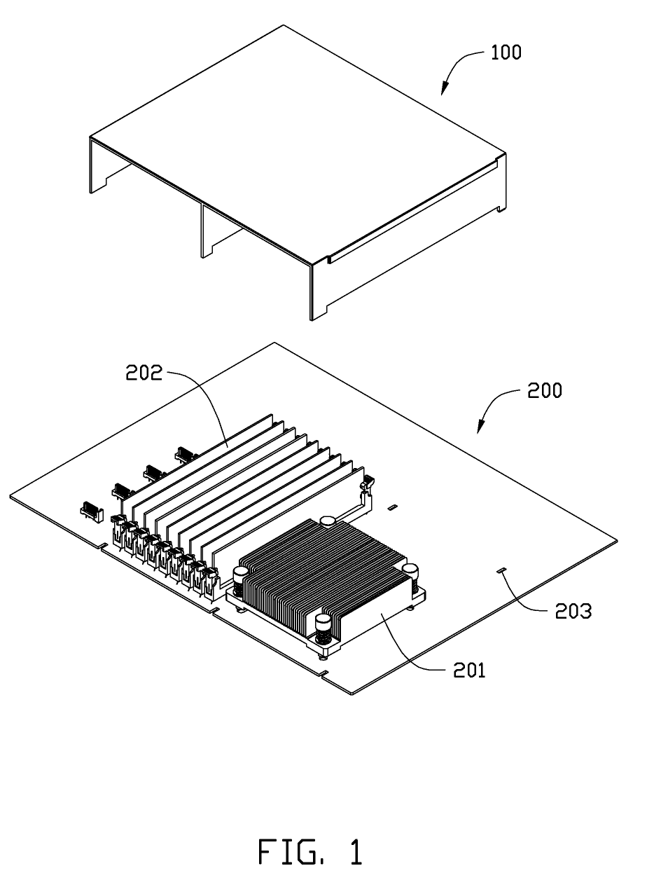

Referring to FIG. 1, an air duct 100 is provided to be set on a circuit board 200 of an electronic device. The circuit board 200 includes a heat sink 201 and a plurality of expansion cards 202 near the heat sink 201. A plurality of locking slots 203 is defined in the circuit board 200 around the head sink 201 and the expansion cards 202.

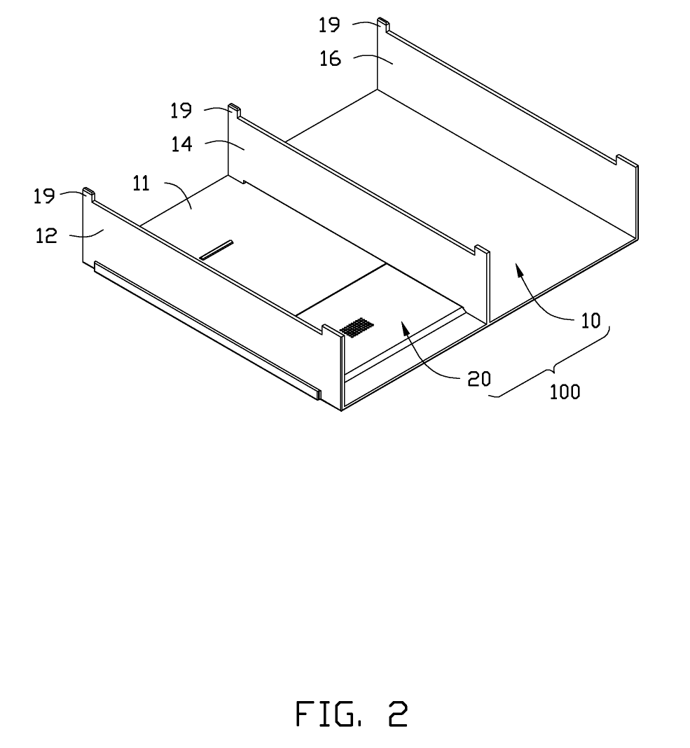

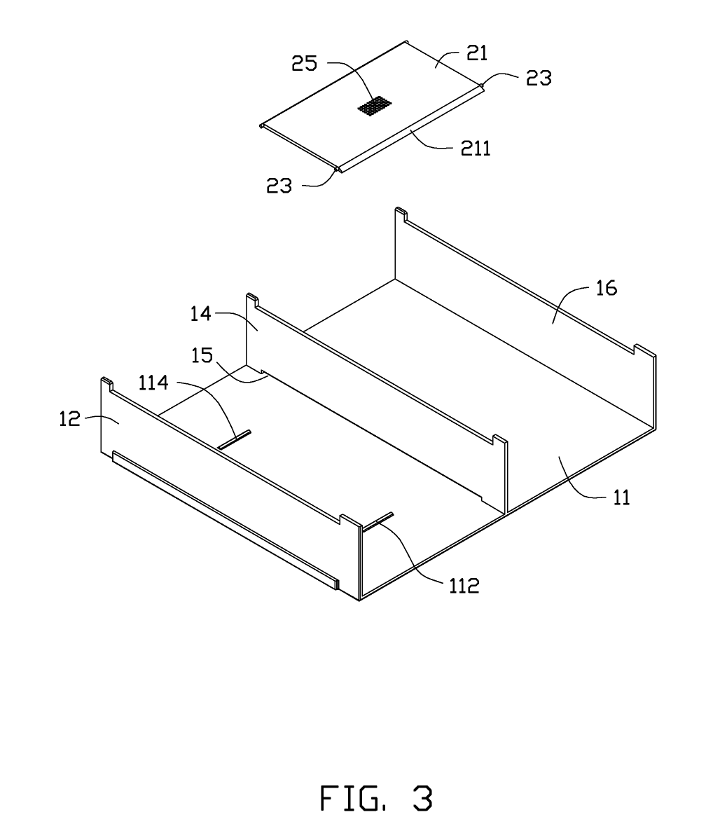

Referring to FIG. 2 and FIG. 3, the air duct 100 includes a cover 10 and an auxiliary plate 20. The cover 10 includes a base plate 11, a first side plate 12 perpendicularly extending from a first end of the base plate 11. A second side plate 16 perpendicularly extending from a second end of the base plate 11, and a third side plate 14 extending perpendicularly from a middle of the base plate 11 between the first and second side plates 12 and 16. The first to third plates 12, 16, 14 are parallel to one another. The first to third plates 12, 16, 14 each form two protrusions 19 at opposite ends of the side plate away from the base plate 11. The first side plate 12 and the third side plate 14 each define a slide slot 15 adjacent to the base plate 11. A first raised portion 112 and a second raised portion 114 are formed on the base plate 11 between the first side plate 12 and the third side plate 14. The first raised portion 112 and the second raised portion 114 are elongated and substantially perpendicular to the first side plate 12.

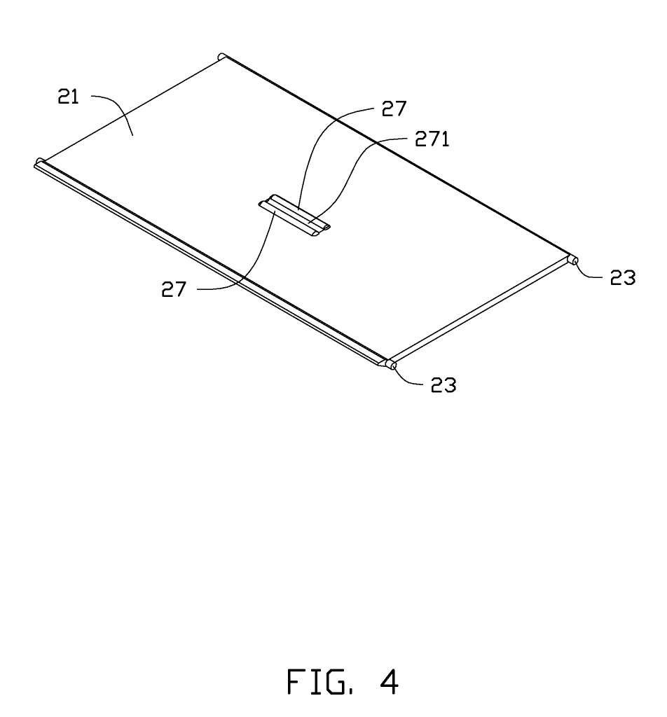

Referring to FIG. 4, the auxiliary plate 20 is a substantially rectangular plate and includes a main body 21. Four pins 23 extend from four corners of the main body 21. Two spaced flanges 27 are formed on a first side surface of the main body 21. A locking slot 271 is defined between the flanges 27. A skidproof portion 25 is formed on a second side surface of the main body 21 opposite to the first side surface, for convenient operation the auxiliary plate 20. A sloped guiding portion 211 is formed from a side of the main body 21.

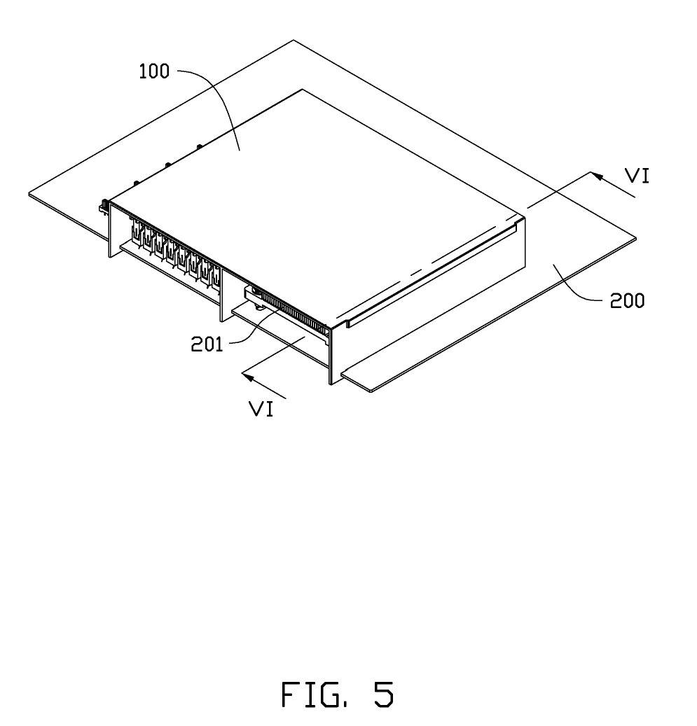

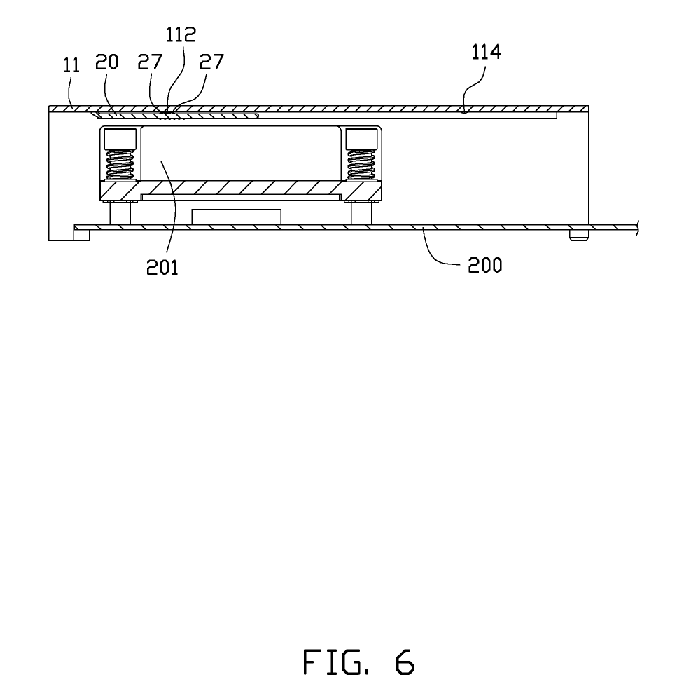

Referring to FIG. 5 and FIG. 6, in assembly, the pins 23 are inserted into the slide slots 15 respectively, to slidably attach the auxiliary plate 20 to the base plate 11 between the first side plate 12 and the third side plate 14. The first raised portion 112 engages in the locking slot 271 to position the auxiliary plate 20 to the cover 10. The protrusions 19 are locked to the locking slots 203 to fix the cover 10 to the circuit board 200. The heat sink 201 is covered by the cover 10 and between the first side plate 12 and the third side plate 14. The expansion cards 202 are covered by the cover 10 and between the third side plate 14 and the second plate 16.

In use, when a space between the heat sink 201 and the base plate 11 is too large to effectively utilize the airflow through the air duct 100, the auxiliary plate 20 is positioned above the heat sink 201 to fill the space between the heat sink 201 and the base plate 11. Therefore, the airflow flowing through the heat sink 201 can effectively dissipate heat from the heat sink 201. The sloped guiding portion 211 guides the airflow.

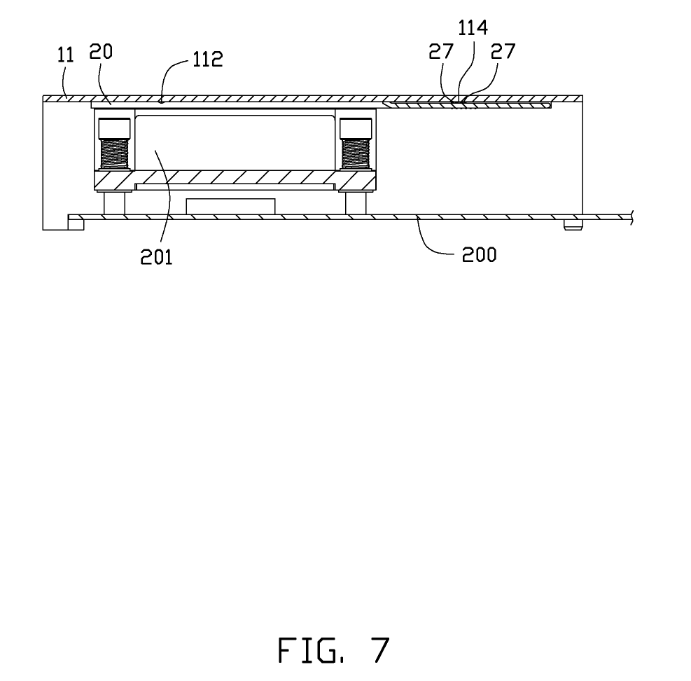

Referring to FIG. 7, when a space between the heat sink 201 and the base plate 11 is too small to effectively utilize the airflow through the air duct 100, the pins 23 are slid in the corresponding slide slots 15. The auxiliary plate 20 is moved away from the heat sink 201, until the second raised portion 112 engages in the locking slot 271 to position the auxiliary plate 20.

In this embodiment, the auxiliary plate 20 adjusts the space between the heat sink 201 and the cover 10 to fit heat sinks having different heights.

It is believed that the present embodiments and theirs advantages will be understood from the foregoing description, and they will be apparent that various changes may be made thereto without departing from the spirit and scope of the description or sacrificing all of their material advantages, the examples hereinbefore described merely being exemplary embodiment.

What is claimed is:

1. An air duct comprising:
a cover comprising a base plate, and a first side plate and a second side plate extending from a first side surface of the base plate; and
an auxiliary plate slidably attached to the first side surface of the base plate between the first side plate and the second side plate, and slidable in a direction substantially parallel to the first and second side plates.

2. The air duct of claim 1, wherein the first and second side plates each define a slide slot, the auxiliary plate comprises a main body and two pins extending from opposite ends of the main body, the pins slidably engage in the slide slots of the corresponding first and second side plates.

3. The air duct of claim 2, wherein two spaced flanges are formed on a first side surface of the main body, a locking slot is defined between the flanges, a first raised portion and a second raised portion are formed from the first side surface of the base plate between the first side plate and the second side plate, either the first raised portion or the second raised portion engages in the locking slot to position the auxiliary plate at two different positions of the base plate, respectively.

4. The air duct of claim 3, wherein a skidproof portion is formed on a second side surface of the main body opposite to the flanges, for convenient operation the auxiliary plate.

5. The air duct of claim 1, wherein the auxiliary plate comprises a sloped guiding portion formed from a side of the auxiliary plate.

6. An electronic device comprising:
a circuit board;
a heat sink set on the circuit board;
a cover fixed to the circuit board and covering the heat sink, the cover comprising a base plate, and a first side plate and a second side plate extending from a first side surface of the base plate toward the circuit board; and
an auxiliary plate slidably attached to the first side surface of the base plate between the first side plate and the second side plate, and slidable in a direction substantially parallel to the first and second side plates.

7. The electronic device of claim 6, wherein the first and second side plates each define a slide slot, the auxiliary plate comprises a main body and two pins extending from opposite ends of the main body, two pins slidably engage in the slide slot of the corresponding first and second side plates.

8. The electronic device of claim 7, wherein two spaced flanges are formed on a first side surface of the main body facing the circuit board, a locking slot is defined between the flanges, a first raised portion and a second raised portion are formed from the first side surface of the base plate between the first side plate and the second side plate, either the first raised portion or the second raised portion engages in the locking slot, to position the auxiliary plate in two positions of the base plate, respectively.

9. The electronic device of claim 8, wherein a skidproof portion is formed on a second side surface of the main body opposite to the circuit board, for convenient operation the auxiliary plate.

10. The electronic device of claim 6, wherein the auxiliary plate comprises a sloped guiding portion formed from a side of the auxiliary plate.

11. The electronic device of claim 6, wherein a plurality of expansion cards are set on the circuit board adjacent to the heat sink, the cover further comprises a third side plate extending from the base plate, the expansion cards are covered by the cover and between the second side plate and the third side plate.
